(19) United States
(12) Patent Application Publication
(10) Pub. No.: US 2024/0275347 A1
(43) Pub. Date: Aug. 15, 2024

(54) CHARGE AMPLIFICATION CIRCUITS AND METHODS

(71) Applicant: STMicroelectronics S.r.l., Agrate Brianza (IT)

(72) Inventors: Roberto MODAFFARI, Pallanzeno (IT); Paolo PESENTI, Senago (IT); Mario MAIORE, Aci Sant'Antonio (IT); Tiziano CHIARILLO, Mascalucia (IT)

(73) Assignee: STMicroelectronics S.r.l., Agrate Brianza (IT)

(21) Appl. No.: 18/634,675

(22) Filed: Apr. 12, 2024

Related U.S. Application Data
(63) Continuation of application No. 17/839,335, filed on Jun. 13, 2022, now Pat. No. 11,984,860.

(30) Foreign Application Priority Data
Jun. 23, 2021 (IT) 102021000016439

(51) Int. Cl. H03F 3/70; G01R 27/26; H03F 3/45

(52) U.S. Cl. CPC H03F 3/70; G01R 27/2605; H03F 3/45968; H03F 2200/375

(57) ABSTRACT

A circuit includes an amplifier, a bias voltage node, and a first set of switches configured, based on a first reset signal having a first value, to couple first and second input nodes to the bias voltage node and to couple first and second output nodes of the amplifier. First and second feedback branches each include a respective RC network including a plurality of capacitances. The first and second feedback branches further include a second set of switches intermediate input nodes and the capacitances, and a third set of switches intermediate input nodes and the plurality of capacitances. These switches selectively couple the capacitances to the input nodes and output nodes, based on a second reset signal having a first value. The second reset signal keeps the first value for a determined time interval exceeding a time interval in which the first reset signal has the first value.

### BACKGROUND

### Technical Field

The description relates to charge amplifier circuits and methods thereof.

One or more embodiments may be applied to capacitive sensors, such as pressure sensors, for instance.

### Description of the Related Art

Charge amplifier circuits are suitable for a variety of electronic applications. For instance, they can be employed in readout chains of capacitive micro-electromechanical systems, MEMS, sensors (that is, sensors configured to transduce a variation of a given physical quantity into a capacitive displacement).

In this context, the charge amplifier is used to convert the variation of charge stored in capacitive elements in a voltage signal, facilitating processing of the signal by further signal processing chains. For instance, in case of a digital signal processing chain, the charge amplifier is coupled to an analog-to-digital converter (briefly, ADC) configured to provide a digital representation of the input voltage signal, optionally applying anti-aliasing filtering.

Existing charge amplifier arrangements may suffer from one or more of the following drawbacks:
presence of an offset error leading to a deterioration of the accuracy,
growth of the detrimental effect of the offset error based on a reduction of the capacitance used in the feedback branch of the amplifier,
growth of the detrimental effect of the offset error based on an increase of the gain from the offset source.

### BRIEF SUMMARY

One or more embodiments of the present disclosure contribute in overcoming the aforementioned drawbacks.

According to one or more embodiments, technical benefits can be achieved by a charge amplifier circuit having the features set forth and described herein.

One or more embodiments may relate to a corresponding capacitive sensor (e.g., pressure sensor).

One or more embodiments may relate to a corresponding method of operating the circuit/device.

One or more embodiments may reduce power consumption, facilitating integrating the charge amplifier in low power application contexts.

One or more embodiments may facilitate compensating, up to eliminating, offset errors in the output voltage signal produced by the charge amplifier circuit.

In one or more embodiments, offset is cancelled in an improved way, e.g., faster.

### BRIEF DESCRIPTION OF THE SEVERAL VIEWS OF THE DRAWINGS

One or more embodiments will now be described, by way of non-limiting example only, with reference to the annexed Figures, wherein:

FIGS. 1 and 2 are exemplary diagrams of a charge amplifier,

FIG. 3 is an exemplary time-diagram of signals in operating the charge amplifier of FIG. 2,

FIG. 4 is an exemplary circuit diagram of an alternative charge amplifier,

FIG. 5 is a circuit diagram exemplary of a charge amplifier circuit as per the present disclosure,

FIG. 6 is a time-diagram exemplary of signals in operating the circuit diagram as per the present disclosure,

FIGS. 7A, 7B and 7C are circuit diagrams exemplary of operative phases of the circuit represented in FIG. 5.

### DETAILED DESCRIPTION

In the ensuing description, one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment” or “in one embodiment” that may be present in one or more points of the present description do not necessarily refer to one and the same embodiment.

Moreover, particular conformations, structures, or characteristics may be combined in any adequate way in one or more embodiments.

Throughout the figures annexed herein, like parts or elements are indicated with like references/numerals and a corresponding description will not be repeated for brevity.

The references used herein are provided merely for convenience and hence do not define the extent of protection or the scope of the embodiments.

For the sake of simplicity, in the following detailed description a same reference symbol may be used to designate both a node/line in a circuit and a signal which may occur at that node or line.

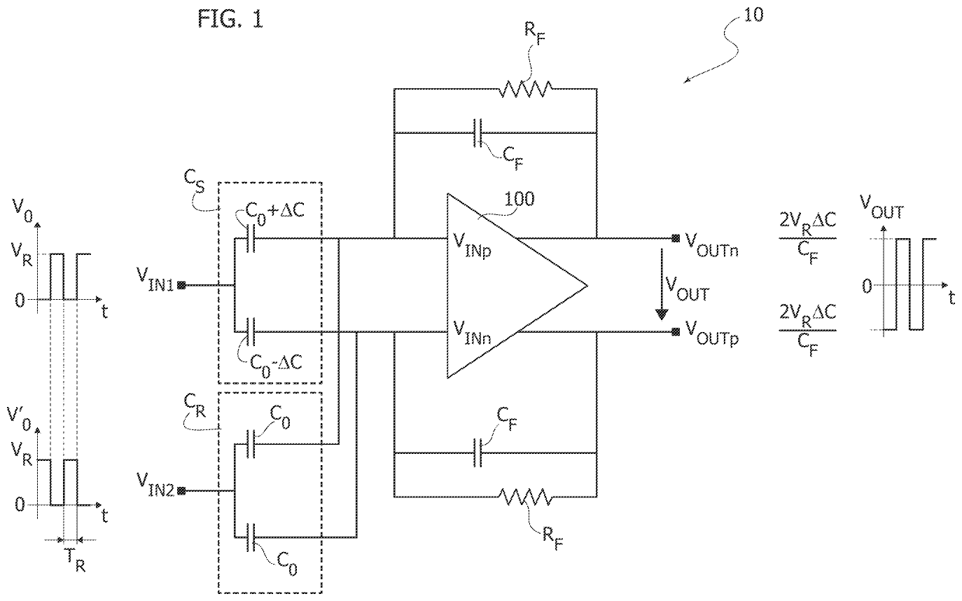

As exemplified in FIG. 1, a (e.g., continuous-time) charge amplifier circuit 10 comprises:
a capacitive sensor C_{S} (e.g., a MEMS sensor) for instance comprises a pair of (e.g., parallel) sensing capacitances C₀, the sensor C_{S} having a first input node V_{IN1} configured to transduce a variation of a physical quantity (for instance, acceleration, position or pressure) into a capacitive displacement ±ΔC in response to a first voltage signal V₀ (e.g., a square waveform with amplitude V_{R} and frequency F_{R}=1/T_{R}) applied to the first input node V_{IN1},
an operational transconductance amplifier (OTA) 100, having:
a first (e.g., non-inverting) input node V_{INp} (e.g., directly) coupled to the sensor C_{S} and to a first output node V_{OUTn} of the OTA 100 via a first feedback branch comprising a first RC network R_{F}, C_{F}, and
a second (e.g., inverting) input node V_{INn} (e.g., directly) coupled to the sensor C_{S} and to a second output node V_{OUTp} via a second feedback branch comprising a second RC network, for instance equal to the first RC network R_{F}, C_{F}.

As mentioned, existing charge amplifier can present an offset error whose recovery time can exceed design constraints. This is due to a large time-constant defined from the big feedback resistance used to bias the virtual ground of this kind of circuits.

Reducing a start-up time in sensor interfaces is particularly relevant in cases where there is a cyclic transition from “normal” operating mode to the “power down” mode, and vice versa. Such a so-called “low power mode” is relevant for applications where power consumption is to be reduced, such as mobile devices having battery life constraints, for instance.

As exemplified in FIG. 1, the charge amplifier 10 is configured to sense a differential charge injected towards its virtual grounds. For instance, in the exemplary case of FIG. 1, the differential charge has a value 2V_{R}ΔC. For instance, it is integrated on feedback capacitance of the stage C_{F}, generating a differential output voltage signal V_{OUT} (e.g., also having a square waveform) which can be expressed as:

$${V}_{OUT} = {V}_{OUTp} - {V}_{OUTn} = 2 {V}_{R} \cdot \frac{Δ C}{{C}_{F}}$$

As exemplified in FIG. 1, the amplifier circuit 10 comprises a reference branch, referred to as “dummy” capacitance C_{R}. For instance, the dummy capacitance C_{R} comprises a replica of the sensing capacitance C₀ at rest (that is, without any signal applied thereto), and has respective input node V_{IN2} configured to receive a second “test” voltage signal V₀′, for instance, in quadrature with the first voltage signal V₀ so that V₀′=not(V₀).

For instance, the capacitive displacement ΔC represents the “sensitivity” of the sensing capacitance C_{S} in response to an external variation of the physical quantity to measure. Such a capacitive variation ΔC associated to the full-scale measurement spaces from 1 fF (1 fF=1 femtoFarad=10-15 Farad) to few tens of fF, for instance.

Taking into account the expression of the differential output voltage signal V_{OUT} discussed in the foregoing and the reduced sensitivity ΔC, relevant in particular for certain kind of capacitive sensors such as MEMS sensors, for instance, it turns out that a high input voltage amplitude V_{R} and small feedback capacitance C_{F} facilitate providing an adequate amplification factor. For instance, an adequate amplification factor refers to a value of gain that properly addresses the performances involved in the whole readout chain.

In order to desirably limit a total power consumption of the whole system, the value of the input voltage V_{R} may be constrained below power supply level. This leads to the feedback capacitance of the amplifier C_{F} remaining as the main design knob available to increase the gain of the stage.

As exemplified in FIG. 1, the resistance R_{F} in the feedback branches R_{F}, C_{F} of the OTA 100 is exploited to set the input common mode V_{CM} of the OTA 100. In the example considered, the feedback resistance R_{F} can be sized so as to render negligible both the discharge of the feedback capacitances C_{F} in a half-period interval T_{R}/2 and the associated thermal noise contribution at the signal frequency F_{R}. To this end Considering the order of magnitude of the capacitances involved, it turns out that the feedback resistances R_{F} can must be selected to be of the order of GΩ (1 GΩ=1 gigaOhm=10⁹Ω), thus having to a negligible thermal noise negligible at signal frequency F_{R}.

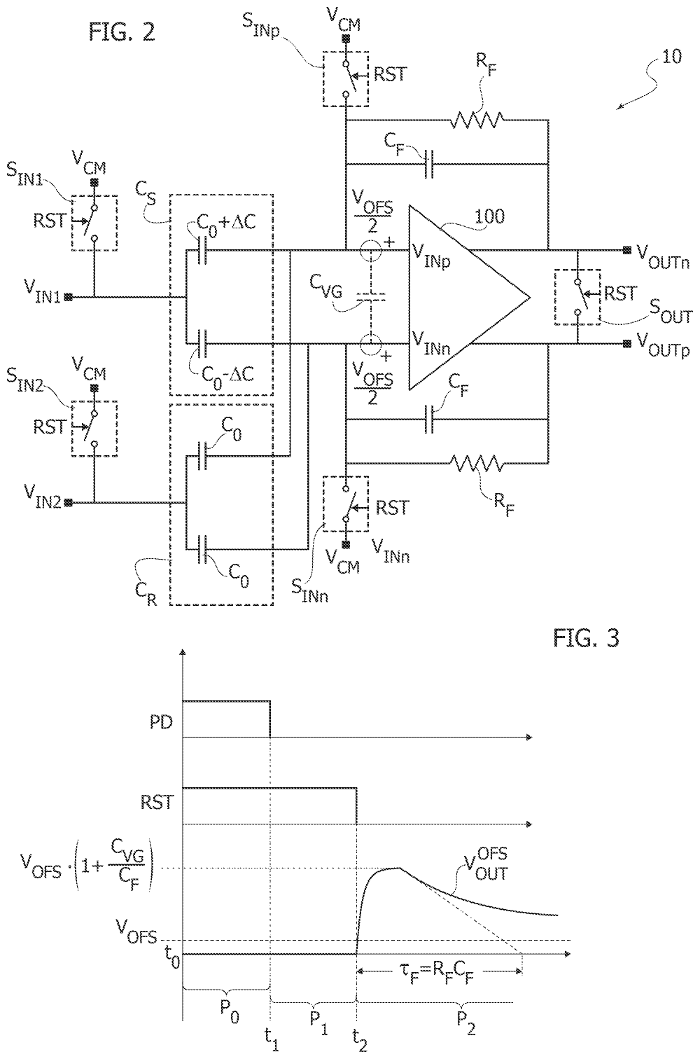

As exemplified in FIG. 2, the charge amplifier circuit 10 may further comprise:
a common mode node V_{CM} configured to receive a common mode voltage level V_{CM}, and
a set of reset switches S_{IN1}, S_{IN2}, S_{INp}, S_{INa}, S_{OUT} comprising:
   a first reset switch S_{IN1} configured to selectively couple the common mode V_{CM} to the first input node V_{IN1},
   a second reset switch S_{IN2} configured to selectively couple the common mode V_{CM} to the second input node V_{IN2},
   a third reset switch S_{INp} configured to selectively couple the common mode V_{CM} to the first V_{INp} input node of the OTA 100,
   a fourth reset switch S_{INn} configured to selectively couple the common mode V_{CM} to the second V_{INn} input node of the OTA 100,
   a fifth reset switch S_{OUT} configured to selectively couple the output nodes of the OTA 100 therebetween.

As exemplified in FIG. 2, reset switches S_{IN1}, S_{IN2}, S_{INp}, S_{INn}, S_{OUT} are driven via a reset signal RST. For instance, the switches S_{IN1}, S_{IN2}, S_{INp}, S_{INp}, S_{OUT} are configured to be in a first (e.g., closed) state when the reset signal RST has a first value (e.g., “1”) and in a second (e.g., open) state when the signal RST has a second value (e.g., “0”).

As exemplified in FIG. 2:
the third and fourth switches S_{INp}, S_{INn} are configured to “short (circuit)” input nodes V_{INp}, V_{INn} of the OTA 100 to the common mode voltage V_{CM},
the fifth switch SW_{OUT} is configured to short the output nodes of the OTA together,
consequently, the first and second switches S_{IN1}, S_{IN2} are configured to reset sensor and dummy capacitances C_{S}, C_{R}.

An arrangement as exemplified in FIG. 2 may present the drawback that a fast start-up may hardly be feasible as hardly any charge stored in the circuit 10 can reach a desired common-mode bias point V_{CM} suitable for such a fast start-up, for instance.

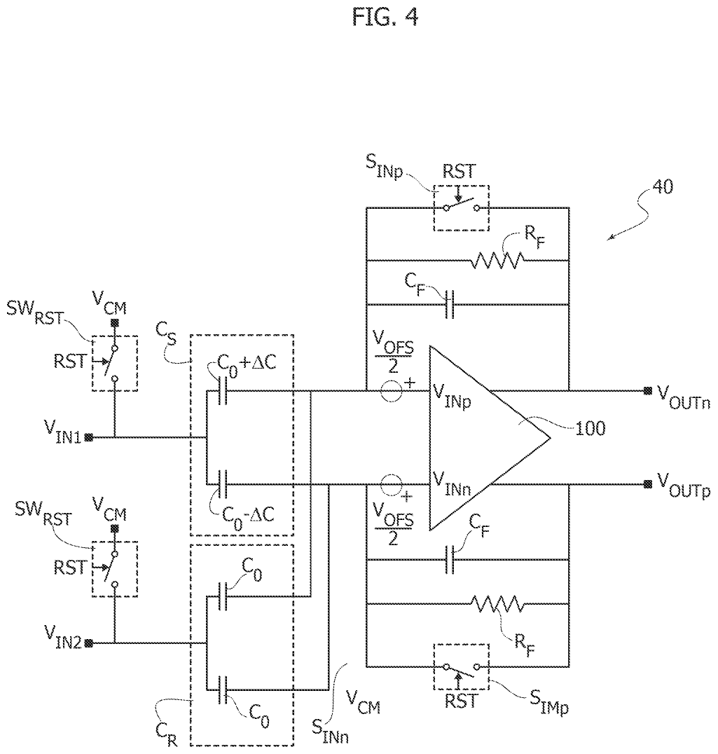

FIG. 3 is a diagram exemplary of signals involved in a start-up phase of the circuit of FIG. 2.

As exemplified in FIG. 3, for instance:
at an initial time t₀, a power-down signal PD is set to a first value (e.g., “1”), initiating a portion P₀ of the start-up phase; for instance, during portion P₀, the circuit 10 is in power-down (e.g., turned “off” state);
at time t₁, in a second portion P₁, the power-down signal is set to a second value (e.g., “0”) and the reset signal RST is set at a first value (e.g., “1”); in other words, after the power-down, the power-on is initiated and the circuit 10 is reset during a phase portion P₁; in particular, the sensor capacitance C_{S} of the sensor and the input nodes of the OTA are coupled to V_{CM} via the switches SW_{RST}, while the outputs of the amplifier are coupled therebetween;
at time t₂, in a third portion P₂, the reset signal RST is set at a second value (e.g., “0”) and capacitances of the sensor C_{S} and the dummy C_{R} are coupled to the respective drive signals V₀, V₀′ and an offset level V_{OFS} at the input nodes varies based on a total capacitance C_{VG} of the virtual ground (represented in dashed lines in FIG. 2) at input nodes V_{INp}, V_{INn} of the OTA 100.

For instance, total capacitance C_{VG} may be expressed as:

$${C}_{V G} = 2 {C}_{0} + {C}_{G} + {C}_{PAR}$$

where:
C₀ is a value of the sensing capacitance of the sensing branches of the sensor C_{S} and of the dummy capacitance C_{R},
C_{G} is the input capacitance of the OTA 100, and
C_{PAR} is a parasitic capacitance, e.g., of the sensor together with the routing.

In one or more embodiments, the sensing capacitance C₀ may have values in a range 100fF-1 pF (1 pF=1 picoFarad=10⁻¹² Farad), based on sensor (manufacturing) technology process.

In one or more embodiments, the (gate) capacitance C_{G} of the OTA 100 may have values about hundreds of fF, in particular for a low noise OTA with low flicker and high input transconductance, for instance.

In one or more embodiments, the parasitic capacitance C_{PAR} may have values in the range about 100fF-1 pf, in particular as it takes into account the contribution of parasitic capacitance from the sensor (e.g., in the pF scale) and of the routing (e.g., hundreds of fF).

It may be possible to express the total offset charge Q_{OFS} transferred on the feedback capacitance C_{F} as:

$${Q}_{OFS} = {V}_{OFS} \cdot {C}_{VG}$$

As a result, the output signal in phase P2, as exemplified in FIG. 3, can be expressed as:

$${V}_{OUT}^{OFS} = {V}_{OFS} \cdot ( 1 + \frac{{C}_{VG}}{{C}_{F}} )$$

As exemplified in FIG. 3, at the beginning of portion P₂, after time t₂, there is a quick injection of offset charge Q_{OFS} in the feedback capacitances C_{F} as soon as the reset signal RST goes to the second value. As soon as the output signal value V_{OUT}^{OFS} is reached, the circuit evolution towards a steady-state condition with output signal equal to offset voltage V_{OFS}, that is V_{OUT}=V_{OFS}. For instance, reaching this steady-state condition involves discharging feedback capacitances C_{F} via the feedback resistances R_{F}, the discharging taking place with a time constant τ_{F}=R_{F}C_{F}.

As exemplified in FIG. 3, this time constant may produce a relatively slow falling trend for the output voltage V_{OUT} (with respect to the rising trend of the output voltage).

As exemplified in FIG. 3, with respect to an “ideal” steady state evolution (represented in dashed line), the steady state condition which may be reached in the circuit of FIG. 2 presents an offset error in the output value V^{OFS}_{OUT}. This may be due, for instance, to an offset factor equal to a ratio C_{VG}/C_{F} of the total capacitance C_{VG} over the feedback capacitance. For instance, the ratio is in a range of values 10 to 50, based on the sensor technology used as well as on the sizing of the feedback capacitance C_{F} of the amplifier, as discussed in the foregoing. As a result of this start-up, the output signal may take a relatively long time to go back to the steady-state offset value V_{OFS} from peak value V_{OUT}^{OFS}.

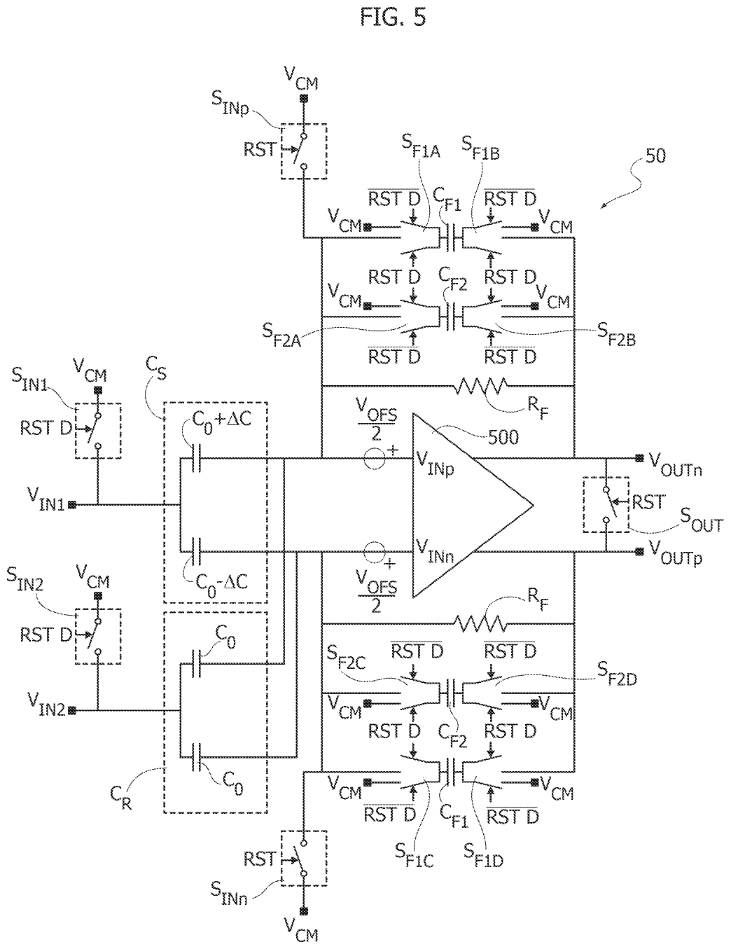

A possible approach to tackle the offset issue is illustrated in FIG. 4.

As exemplified in FIG. 4, third and fourth reset switches S_{INp}, S_{INn} are coupled across input and output nodes of the amplifier 100 in place of the common mode voltage V_{CM} (as exemplified in FIG. 2). In this way, for instance, during reset phase (e.g., RST=“1”) the offset is stored on the total capacitance C_{VG}, but no charge is transferred to the feedback capacitance C_{F}. As a result, once reset is released (e.g., RST=“0”) the circuit 40 has already applied the offset voltage at its output nodes, speeding up startup.

A solution as exemplified in FIG. 4 may still present some drawbacks and limited applicability in low-power applications. For instance, the ratio C_{VG}/C_{F} among capacitances C_{VG} and C_{F} is a relevant parameter for both offset amplification factor and feedback gain attenuation.

For instance, the feedback gain attenuation has a positive impact on the stability of the circuit, reducing a Gain-BandWidth Product (briefly, GBWP) of the closed-loop amplifier by an amount equal to the ratio C_{VG}/C_{F}. For instance, this facilitates reducing current consumption of an output stage where a multi-stage OTA is used.

In existing solutions, a buffer configuration of the OTA may be used in order to cancel the offset-related error. In this case, there are no capacitive partitions and consequently no positive impact on the GBWP. This can lead to an increased risk of instability. To counter this increased instability, existing solutions envisage increasing current consumption. These solutions are hardly compatible with low power applications.

A solution as discussed herein facilitates offset cancellation while involving a reduced effort with respect to that associated to the stabilization of the OTA 100 at its GBWP frequency, consequently countering the otherwise involved increase of current consumption.

In one or more embodiments, introducing a delayed reset phase may facilitate overcoming aforementioned limitations in terms of stability and power consumption.

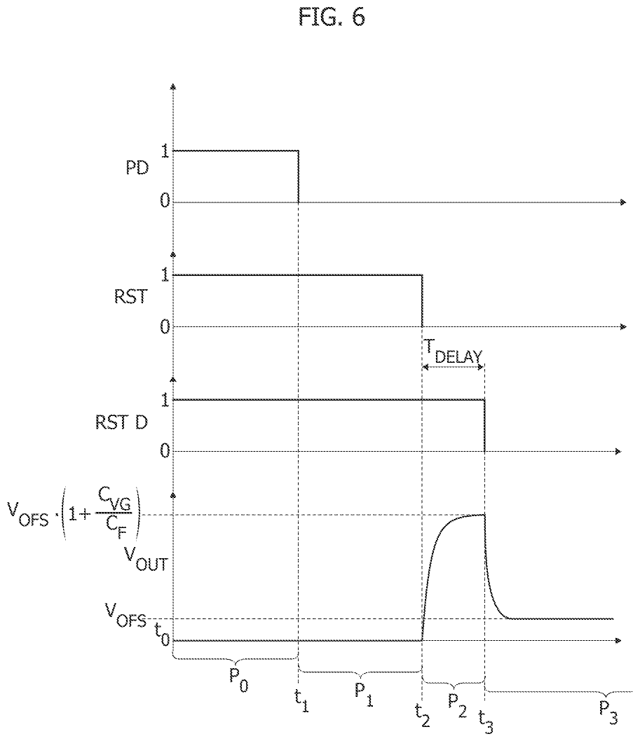

As exemplified in FIG. 5, the charge amplifier circuit 50 comprises an operational transconductance amplifier (OTA) 500 including:
a first (e.g., non-inverting) input node V_{INp} (e.g., directly) configured to be coupled to the capacitive sensor C_{S} and to a first output node V_{OUTn} of the OTA 100 via a first feedback branch comprising a first RC network R_{F}, C_{F1}, C_{F2}, including at least a first capacitance C_{F1} and a second capacitance C_{F2}, e.g., in parallel therebetween, and
a second (e.g., inverting) input node V_{INn} (e.g., directly) coupled to the capacitive sensor C_{S} and to a second output node V_{OUTp} via a second feedback branch comprising a second RC network, for instance equal to the first RC network R_{F}, C_{F1}, C_{F2},
a common mode node V_{CM} configured to receive a common mode voltage level V_{CM},
a first set of reset switches S_{IN1}, S_{IN2}, S_{INp}, S_{INp}, S_{OUT} configured to be driven by a first reset signal RST, the first set of reset switches S_{IN1}, S_{IN2}, S_{INp}, S_{INp}, S_{OUT} arranged and configured to operate along the lines of like referenced reset switches discussed in the foregoing with respect to FIG. 2,
a second set of switches S_{F1A}, S_{F1B}, S_{F1C}, S_{F1D}, S_{F2A}, S_{F2B}, S_{F2C}, S_{F2D} configured to be driven by a second “delayed” reset signal RSTD, switches in the second set of switches S_{F1A}, S_{F1B}, S_{F1C}, S_{F1D}, S_{F2A}, S_{F2B}, S_{F2C}, S_{F2D} being configured to couple capacitances C_{F1}, C_{F2} in the first and second feedback branches of the OTA 500 to the input V_{INp}, V_{INn} and/or output nodes V_{OUTp}, V_{OUTn} thereof.

For instance, the feedback capacitances C_{F1}, C_{F2} in the feedback branches of the OTA 500 can be equal, e.g., C_{F}1=C_{F}2=C_{F}.

A circuit as exemplified herein, comprises:
an amplifier (for instance, 500) having a first input node (for instance, V_{INp}) and a second input node (for instance, V_{INn}) configured to be coupled to opposite ends of at least one capacitance (for instance, Cs, CD) to detect therefrom a capacitive variation signal (for instance, ΔC) indicative of variations in the value of the at least one capacitance, the amplifier (e.g., single stage or multi-stage OTA) having a first output node (for instance, V_{OUTp}) and a second output node (for instance, V_{OUTn}),
a bias voltage node (for instance, V_{CM}) configured to provide a bias voltage level,
a first set of switches (for instance, S_{INp}, S_{INn}, S_{OUT}) configured, based on a first reset signal (for instance, RST) having a first value, to couple the first and second input nodes of the amplifier to the bias voltage node and to couple therebetween the first and second output nodes of the amplifier,
a first feedback branch (for instance, R_{F}, C_{F1}, C_{F2}) comprising a first RC network including a first and a second capacitance (for instance, C_{F1}, C_{F2}), the first feedback branch coupled between the first output node and the first input node of the amplifier,
a second feedback branch (for instance, R_{F}, C_{F1}, C_{F2}) comprising a second RC network including a third and a fourth capacitance (for instance, C_{F1}, C_{F2}), the second feedback branch coupled between the second output node and the second input node of the amplifier,
the first and second feedback branches further comprising:
   a second set of switches (for instance, S_{F1A}, S_{F1C}, S_{F2A}, S_{F2C}) intermediate the first and second input nodes of the amplifier and the first, second, third and fourth capacitances, and
   a third set of switches (for instance, S_{F1B}, S_{F1D}, S_{F2B}, S_{F2D}) intermediate the first and second output nodes of the amplifier and the first, second, third and fourth capacitances,
   wherein
      the switches in the second set of switches are configured to selectively couple one of the first and second capacitances in the first feedback branch and one of the third and fourth capacitances in the second feedback branch to the first and second input nodes of the amplifier based on a second reset signal (for instance, RSTD) having a first value,
      the switches in the third set of switches are configured to selectively couple said one of the first and second capacitances in the first feedback branch and said one of the third and fourth capacitances in the second feedback branch to the first and second output nodes of the amplifier (500) based on a second reset signal having a first value,
      wherein the first reset signal is configured to have a first value for a first time interval (for instance, P0, P1) and to switch (for instance, t₂) from the first value to a second value after the first time interval,
      wherein, in response to the first reset signal switching from the first value to the second value, the second reset signal maintains said first value for a further time interval (for instance, P₂, T_{DELAY}) exceeding the first time interval during which the first reset signal has the first value.

As exemplified herein, the circuit comprises a power supply of the amplifier, the power supply configured to be powered-down based on a power-down (for instance, PD) signal having a first value, the first time interval in which the first reset signal is configured to have the first value comprises a first sub-interval (for instance, P0) and a second sub-interval (for instance, P1), the power-down signal has a first value during the first sub-interval and a second value during the second sub-interval, the power supply of the amplifier being powered-down during the first sub-interval as a result.

As exemplified herein, the amplifier has a signal amplification bandwidth and wherein the further time interval (for instance, P2, T_{DELAY}) exceeding the time interval during which the first reset signal has the first value has a time duration that is a function of the signal amplification bandwidth of the amplifier.

As exemplified herein, the amplifier is a fully differential (e.g., multi stage or single stage) operational trans-conductance amplifier, OTA.

As exemplified herein, the second feedback branch is a replica of the first feedback branch.

For instance:
the first feedback branch comprises the parallel connection of the first capacitance and the second capacitance, said parallel connection in turn arranged in parallel to a resistance (for instance, R_{F}),
the second set of switches comprises:
   a first switch (for instance, S_{F1A}) interposed between the first input node of the amplifier and the first capacitance (for instance, C_{F1}),
   a second switch (for instance, S_{F2A}) interposed between the first input node of the amplifier and the second capacitance (for instance, C_{F2}),
the third set of switches comprises:
   a respective first switch (for instance, S_{F1B}) interposed the first output node of the amplifier and the first capacitance,
   a respective second switch (for instance, S_{F2B}) interposed between the first output node of the amplifier circuit and the second capacitance (for instance, C_{F2}).

A sensor device (for instance, 50) as exemplified herein, comprises:
at least one detecting capacitance (for instance, Cs) configured to transduce a variation of a physical quantity into a capacitive variation signal (for instance, ΔC),
a reference capacitive element (for instance, C_{R}) coupled to the at least one capacitance, the reference capacitive element having a value of capacitance substantially equal to a value of capacitance at rest (for instance, C₀) of the at least one capacitance,
a circuit as per the present disclosure having input nodes (for instance, V_{INp}, V_{INn}) coupled at ends of the at least one detecting capacitance and at ends of the reference capacitive element,
control circuitry coupled to the circuit and configured to provide a first reset signal (for instance, RST) and a second reset signal (for instance, RSTD) thereto,
wherein the first reset signal is configured to have a first value for a first time interval and to switch from the first value to a second value after the first time interval,
wherein, in response to the first reset signal (RST) switching from the first value to the second value, the second reset signal maintains said first value for a further time interval (for instance, T_{DELAY}) exceeding the first time interval (for instance, P0, P1) during which the first reset signal has the first value.

As exemplified herein, the sensor comprises a further set of switches (for instance, S_{IN1}, S_{IN2}) configured to couple an input node (for instance, V_{IN1}) of the sensing capacitance and an input node (for instance, V_{IN2}) of the reference capacitive element to the bias voltage node based on the second reset signal having a first value.

In one or more embodiments, performing a reset phase of the OTA stage 500 in the circuit 50 comprises:
in a first reset phase, based on a first reset signal RST, coupling the virtual grounds and the shortcut of the two output nodes, and
in a second reset phase, based on a second reset signal RSTD, performing further acts as discussed in the following, the second reset phase delayed of a time interval with respect to the first reset phase, the time interval determined based on a bandwidth of the OTA 500.

For instance, the second reset signal RSTD controls the feedback capacitance and input nodes of the OTA circuit 500, as discussed in the following.

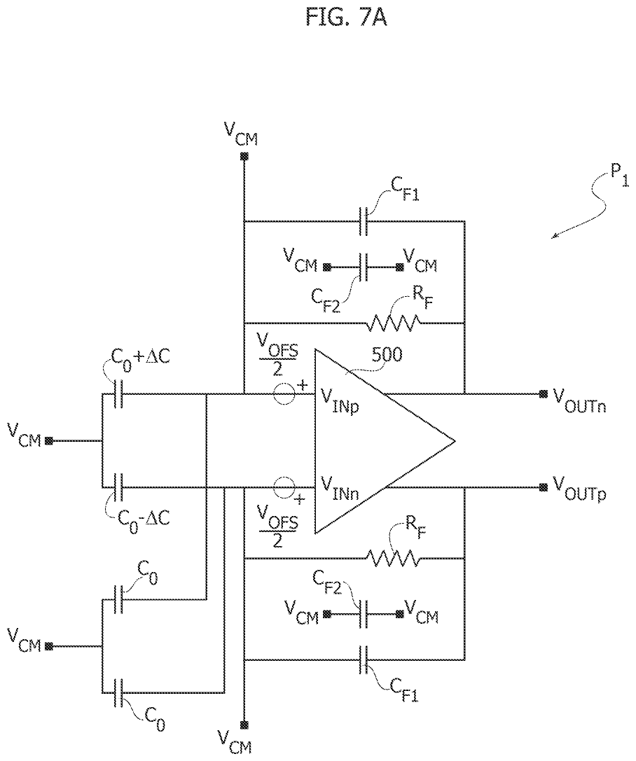

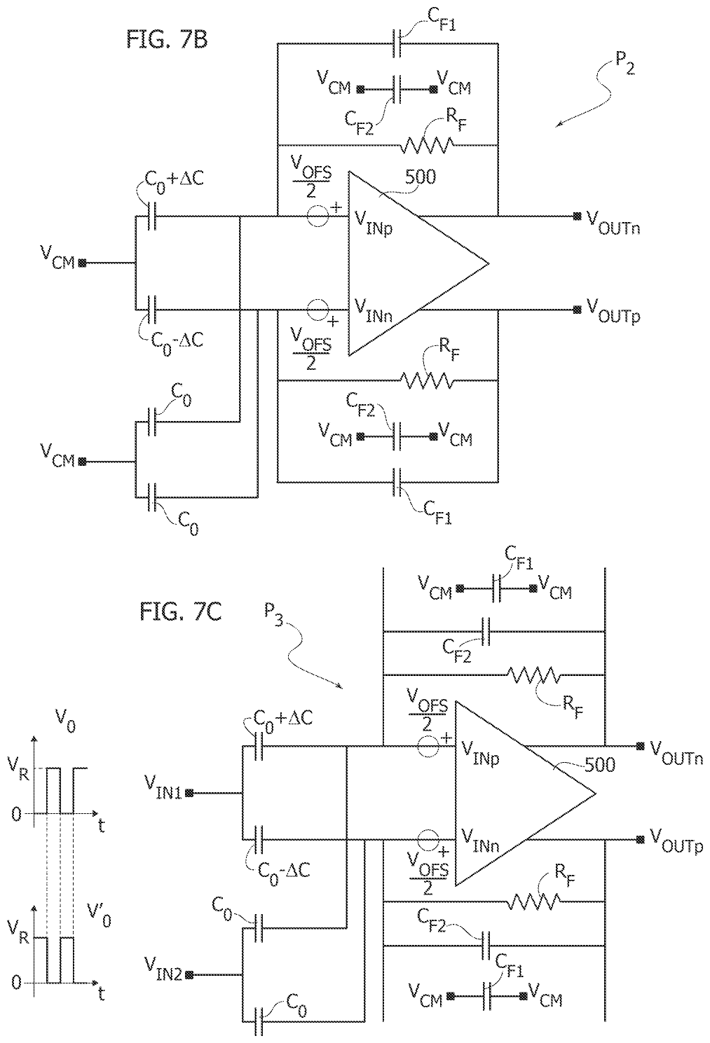

As exemplified in FIG. 6:
at initial time t₀, during initial phase P0, the circuit 50 is off and stays turned off until the power-down signal PD is at a first signal level (e.g., “1”),
at time instant t₁, ending phase P0 and initiating phase P1, the power-down signal switches to a second signal level (e.g., “0”) while the first reset signal RST and the second reset signal RSTD are at the first signal level (e.g., “1”). FIG. 7A is exemplary of the circuit 50 during phase P1. As exemplified in FIG. 7A, switches in the first set of switches S_{IN1}, S_{IN2}, S_{INp}, S_{INp}, S_{OUT}, and switches in the second set of switches S_{F1A}, S_{F1B}, S_{F2A}, S_{F2B}, S_{F1C}, S_{F1D}, S_{F2C}, S_{F2D} are in a first (e.g., “closed”) state and couple respective nodes to the common-mode bias voltage level V_{CM}, leading to discharge of all the capacitances C_{F1}, C_{F2} in the feedback branches of the OTA 500. As a result (see, e.g., FIG. 6), output differential voltage level V_{OUT} during phase P₁ is at a ground level.

As exemplified in FIG. 6, at time instant t₂, ending phase P1 and initiating phase P2, the first reset signal RST switches to the second signal level (e.g., “0”) while the second reset switch RSTD remains in the first signal level (e.g., “1”). FIG. 7B is exemplary of the circuit 50 during phase P2. As exemplified in FIG. 7B, the fifth S_{OUT} in the first set of switches S_{IN1}, S_{IN2}, S_{INp}, S_{INp}, is released and goes to the second state (e.g., “open”) while switches in the second set of switches S_{F1A}, S_{F1B}, S_{F2A}, S_{F2B}, S_{F1C}, S_{F1D}, S_{F2C}, S_{F2D} remain in a first (e.g., “closed”) state and couple respective nodes to the common-mode bias voltage level V_{CM}.

As exemplified in FIGS. 6 and 7B, during phase P2, offset voltage V_{OFS} is transferred to the output nodes V_{OUTp}, V_{OUTn} and amplified by amplification factor (1+C_{VG}/C_{F}), where the charge V_{OFS}*C_{VG} is stored both in the C_{VG} and C_{F1} while the capacitance C_{F2} is shorted to the common bias voltage V_{CM}.

As exemplified in FIG. 7B, in order to avoid the cancelation of the signal, input node V_{IN1} of the circuit 15 remains coupled to common mode level V_{CM} during phase P2.

As exemplified in FIG. 6, at time t3, ending phase P2 and initiating phase P3, the second reset switch RSTD switches to a second signal level (e.g., “0”). FIG. 7C is exemplary of the circuit 50 during phase P3. As exemplified in FIG. 7C, based on the second reset signal RSTD, switches in the second set of switches S_{F1A}, S_{F1B}, S_{F2A}, S_{F2B}, S_{F1C}, S_{F1D}, S_{F2C}, S_{F2D} are driven so that the first feedback capacitance C_{F1} is decoupled from the OTA 500 and discharged to common move voltage level V_{CM} while the second feedback capacitance C_{F2} starts from a discharged state. As exemplified in FIGS. 6 and 7C, output differential voltage V_{OUT} at the output nodes V_{OUTn}, V_{OUTp} of the OTA 500 reach the steady-state voltage value V_{OFS} during phase P3. For instance, a time interval T_{DELAY} between second t₂ and third t₃ time intervals is equal to the time constant for reaching this steady state condition.

As exemplified in FIG. 6, the time interval T_{DELAY} has a duration determined based on the bandwidth of the amplifier, which is order of magnitude higher than the “slow” time constant of the feedback network τ_{F}=R_{F}C_{F}.

A method of operating a circuit or a sensor device as per the present disclosure, comprises:
providing a bias voltage node configured to provide a bias voltage level (for instance, V_{CM}),
driving the first set of switches (for instance, S_{INp}, S_{INn}, S_{OUT}), based on a first reset signal (for instance, RST), to couple the input nodes of the amplifier circuit to the bias voltage node (V_{CM}) and to couple the first and second output nodes of the amplifier circuit therebetween,
driving switches in the second set of switches (for instance, S_{F1A}, S_{F1C}, S_{F2A}, S_{F2C}) to selectively couple one of the first (for instance, C_{F1}) and second (for instance, C_{F2}) capacitances in the first feedback branch (for instance, C_{F1}, C_{F2}, R_{F}) and one of the third (for instance, C_{F1}) and fourth (for instance, C_{F2}) capacitances in the second feedback branch (for instance, R_{F}, C_{F1}, C_{F2}) to the first (for instance, V_{INp}) and second (for instance, V_{INn}) input nodes (for instance, V_{INn}, V_{INp}) of the amplifier based on a second reset signal (for instance, RSTD) having a first value, and
driving the switches in the third set of switches (for instance, S_{F1B}, S_{F1D}, S_{F2B}, S_{F2D}) to couple said one of the first and second capacitances in the first feedback branch and said one of the third and fourth capacitances in the second feedback branch to the first (for instance, V_{OUTp}) and second (for instance, V_{OUTn}) output nodes (V_{OUTn}, V_{OUTp}) of the amplifier based on a second reset signal (for instance, RSTD) having a first value,
switching (for instance, t₂) the first reset signal from the first value to a second value after elapse of a first time interval,
in response to the first reset signal switching from the first value to the second value, maintaining the second reset signal at said first value for a further time interval (for instance, T_{DELAY}) exceeding the first time interval (for instance, P0, P1) during which the first reset signal has the first value.

As exemplified in FIG. 7C, after complete discharge, the input nodes V_{IN1}, V_{IN2} can be coupled to the input square waveforms V₀, V₀′.

It will be otherwise understood that the various individual implementing options exemplified throughout the figures accompanying this description are not necessarily intended to be adopted in the same combinations exemplified in the figures. One or more embodiments may thus adopt these (otherwise non-mandatory) options individually and/or in different combinations with respect to the combination exemplified in the accompanying figures.

Without prejudice to the underlying principles, the details and embodiments may vary, even significantly, with respect to what has been described by way of example only, without departing from the extent of protection.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A circuit, comprising:
an amplifier;
a bias voltage node;
a first set of switches coupled to the amplifier and the bias voltage node;
a first feedback branch coupled to the amplifier, the first feedback branch including a first RC network including a first and a second capacitance;
a second feedback branch to the amplifier, the second feedback branch including a second RC network including a third and a fourth capacitance;
the first and second feedback branches further including:
a second set of switches; and
a third set of switches;
wherein the switches in the second set of switches are configured to selectively couple one of the first and second capacitances in the first feedback branch and one of the third and fourth capacitances in the second feedback branch to the amplifier in response to a first reset signal; and
the switches in the third set of switches are configured to selectively couple the one of the first and second capacitances in the first feedback branch and the one of the third and fourth capacitances in the second feedback branch to the amplifier in response to a second reset signal.

2. The circuit of claim 1, wherein the amplifier has a first input node, a second input node, a first output node, and a second output node.

3. The circuit of claim 2, wherein the first feedback branch is coupled between the first output node and the first input node of the amplifier and the second feedback branch is coupled between the second output node and the second input node of the amplifier.

4. The circuit of claim 2, wherein the second set of switches is coupled between the first and second input nodes of the amplifier and the first, second, third, and fourth capacitances.

5. The circuit of claim 2, wherein the third set of switches is coupled between the first and second output nodes of the amplifier and the first, second, third, and fourth capacitances.

6. The circuit of claim 2, wherein the first set of switches includes an output switch coupled between the first output node and the second output node.

7. A circuit, comprising:
an amplifier circuit;
a capacitive sensor circuit coupled to a first and second input of the amplifier circuit, the capacitive sensor circuit including a plurality of sensing capacitances;
a first set of switches coupled to the capacitive sensor circuit;
a first feedback branch coupled between the first input and a first output of the amplifier circuit, the first feedback branch including a first capacitance and a second capacitance;
a second feedback branch coupled between the second input and a second output of the amplifier circuit, the second feedback branch including a third capacitance and a fourth capacitance;
a second set of switches that selectively couple one of the first and second capacitances in the first feedback branch and one of the third and fourth capacitances in the second feedback branch to the amplifier; and
a third set of switches.

8. The circuit of claim 7, wherein the plurality of sensing capacitances are coupled in parallel.

9. The circuit of claim 7, wherein the first feedback branch includes a first resistor and the second feedback branch includes a second resistor.

10. The circuit of claim 7, wherein the first capacitance is coupled in parallel with the second capacitance and the third capacitance is coupled in parallel with the fourth capacitance.

11. The circuit of claim 9, wherein the first resistor has a first resistance equal to a second resistance of the second resistor.

12. The circuit of claim 7, wherein the first set of switches is driven by a first reset signal and the second set of switches is driven by a second reset signal.

13. The circuit of claim 12, wherein the first reset signal has a first value for a first time interval and switches to a second value after the first time interval.

14. The circuit of claim 13, wherein, in response to the first reset signal switching to the second value, the second reset signal maintains the first value for a second time interval that is longer than the first time interval.

15. The circuit of claim 7, wherein the switches in the third set of switches are configured to selectively couple the one of the first and second capacitances in the first feedback branch and the one of the third and fourth capacitances in the second feedback branch to the amplifier in response to a reset signal.

16. The circuit of claim 7, wherein the first, second, third, and fourth capacitances are all equal.

17. A method of operating a circuit, comprising:
forming a bias voltage level in a bias voltage node, the bias voltage node coupled to a first set of switches and a capacitive sensor circuit, the capacitive sensor circuit coupled to a first and second input of an amplifier circuit;
driving the first set of switches, based on a first reset signal, to couple the first and second inputs of the amplifier circuit to the bias voltage node;
driving a second set of switches, based on a second reset signal, to selectively couple one of a first and second capacitances in a first feedback branch to the first and second input nodes of the amplifier, the first feedback branch being coupled between the first input and a first output of the amplifier circuit;
driving a third set of switches, based on the second reset signal, to couple one of the first and second capacitances in the first feedback branch to the first output node and a second output node of the amplifier;
switching the first reset signal from a first value to a second value after a first time interval; and
maintaining, in response to the switching the first reset signal from the first value to the second value, the second reset signal at the first value for a second time interval that is greater than the first time interval.

18. The method of claim 17, wherein the driving the first set of switches includes driving the first set of switches to couple the first output node and the second output node of the amplifier circuit.

19. The method of claim 17, further comprising:
selectively coupling one of a third and fourth capacitances in a second feedback branch to the first and second input nodes of the amplifier, the second feedback branch being coupled between the second input and the second output node of the amplifier circuit by driving the second set of switches, based on the second reset signal.

20. The method of claim 17, further comprising:
coupling one of the third and fourth capacitances in the second feedback branch to the first output node and the second output node of the amplifier circuit by driving the third set of switches, based on the second reset signal.
